(19) United States
(12) Patent Application Publication
(10) Pub. No.: US 2025/0306572 A1
(43) Pub. Date: Oct. 2, 2025

(54) INFORMATION PROCESSING APPARATUS, RECIPE EDITING METHOD, AND SEMICONDUCTOR MANUFACTURING APPARATUS

(71) Applicant: Tokyo Electron Limited, Tokyo (JP)

(72) Inventor: Tatsuya YAMAGUCHI, Yamanashi (JP)

(21) Appl. No.: 19/082,969

(22) Filed: Mar. 18, 2025

(30) Foreign Application Priority Data
Mar. 27, 2024 (JP) 2024-051106

(51) Int. Cl. G05B 19/418; G06F 3/04847; H01L 21/67

(52) U.S. Cl. CPC G05B 19/41835; G06F 3/04847; G05B 2219/45031; H01L 21/67069

(57) ABSTRACT

An information processing apparatus includes a display block operation reception unit that receives, by an operation of an operator of arranging, on a screen, a plurality of display blocks visually indicating setting of at least one category included in a recipe to be executed by a semiconductor manufacturing apparatus, an input of a time during which the setting of the category continues; a property setting input reception unit that receives, from the operator, an input of a setting value of a setting item included in the setting; and a recipe edition unit that edits the recipe by sequentially arranging steps, each made up of a combination of all setting items set with the setting values and the time during which the setting continues, as a minimum unit, based on the time during which the setting setting continues and the input of the setting value of the setting item.

### CROSS-REFERENCE TO RELATED APPLICATIONS

This application is based on and claims priority from Japanese Patent Application No. 2024-051106, filed on Mar. 27, 2024, with the Japan Patent Office, the disclosure of which is incorporated herein in its entirety by reference.

### TECHNICAL FIELD

The present disclosure relates to an information processing apparatus, a recipe editing method, and a semiconductor manufacturing apparatus.

### BACKGROUND

A semiconductor manufacturing apparatus performs processes by executing recipes that combine settings for various categories such as temperature, gas, pressure, plasma, and mechanics. For example, Japanese Patent Laid-Open Publication No. 2023-169963 describes a technique that allows easy visual confirmation of the comparison results of multiple recipes.

### SUMMARY

According to an aspect of the present disclosure, an information processing apparatus includes a display block operation reception unit that receives, by an operation of an operator of arranging, on a screen, a plurality of display blocks visually indicating setting of at least one category among a plurality of categories included in a recipe to be executed by a semiconductor manufacturing apparatus, an input of a time during which the category setting continues, a property setting input reception unit configured to receive, from the operator, an input of a setting value of a setting item included in the setting of the category for each display block arranged on the screen, and a recipe edition unit that edits the recipe by sequentially arranging steps, each made up of a combination of all setting items set with the setting values and the time during which the setting continues, as a minimum unit, based on the time during which the category setting continues and the input of the setting value of the setting item.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram illustrating an example of a semiconductor manufacturing system according to the present embodiment.

FIG. 2 is a hardware configuration diagram illustrating an example of a computer.

FIG. 3 is a functional block diagram illustrating an example of an apparatus controller according to the present embodiment.

FIG. 4 is a configuration diagram illustrating an example of a recipe to be executed by a semiconductor manufacturing apparatus.

FIG. 5 is a configuration diagram illustrating an example of setting items for a temperature category.

FIG. 6 is a configuration diagram illustrating an example of a recipe in which the same setting values are input.

FIG. 7 is a configuration diagram illustrating an example of a recipe in which continuously varying setting values are input.

FIG. 8 is a configuration diagram illustrating an example of a recipe in which continuously varying setting values are input.

FIG. 9 is a configuration diagram illustrating an example of a recipe in which while the temperature is varying due to continuously varying setting values, setting values for other categories are changed at different step times.

FIG. 10 is a configuration diagram illustrating an example of a recipe in which each category has its own step time.

FIG. 11 is an image diagram illustrating an example of a recipe editing screen according to the present embodiment.

FIG. 12 is a diagram illustrating a “Temperature Rise to 500° C.” display block as an example of a temperature block.

FIG. 13 is a diagram illustrating a “Temperature Drop to 400° C.” display block as an example of a temperature block.

FIG. 14 is a diagram illustrating a “Load at 400° C.” display block as an example of a temperature block.

FIG. 15 is a diagram illustrating a “SVAC” display block as an example of a pressure block.

FIG. 16 is a diagram illustrating a “MV Open” display block as an example of a pressure block.

FIG. 17 is a diagram illustrating a “MV Close” display block as an example of a pressure block.

FIG. 18 is a diagram illustrating a “Pressure Control” display block as an example of a pressure block.

FIG. 19 is a diagram illustrating an “ATM” display block as an example of a pressure block.

FIG. 20 is a diagram illustrating “N2,” “SiH4,” and “NH3” display blocks as examples of gas blocks.

FIG. 21 is a diagram illustrating a “Rotate” display block as a mechanical boat rotation block, a “Load” display block as a mechanical boat ELV block, and an “Unload” display block as a mechanical boat ELV block.

FIG. 22 is a diagram illustrating an “ALD” display block as an example of a special film formation block.

FIG. 23 is a diagram illustrating a “TVS” display block as an example of a special film formation block.

FIG. 24 is an explanatory diagram illustrating an example of a recipe editing area where display blocks are arranged.

FIG. 25 is an explanatory diagram illustrating an example of a recipe editing area where display blocks are arranged.

FIG. 26 is an explanatory diagram illustrating an example of a recipe editing area where display blocks are arranged.

FIG. 27 is a diagram illustrating setting for visually indicated checks in a recipe editing area.

FIG. 28 is a diagram illustrating setting for visually indicated checks in a recipe editing area.

FIG. 29 is an image diagram illustrating an example of a process for editing a recipe with an existing recipe structure based on the arrangement of display blocks in a recipe editing area and property setting input to a property setting area.

FIG. 30 is a flowchart illustrating an example of a process for conversion to an existing recipe structure.

FIG. 31 is an image diagram illustrating an example of a process for editing a recipe with an existing recipe structure based on the arrangement of display blocks in a recipe editing area and property setting input to a property setting area.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, the present embodiment will be described with reference to the drawings.

### System Configuration

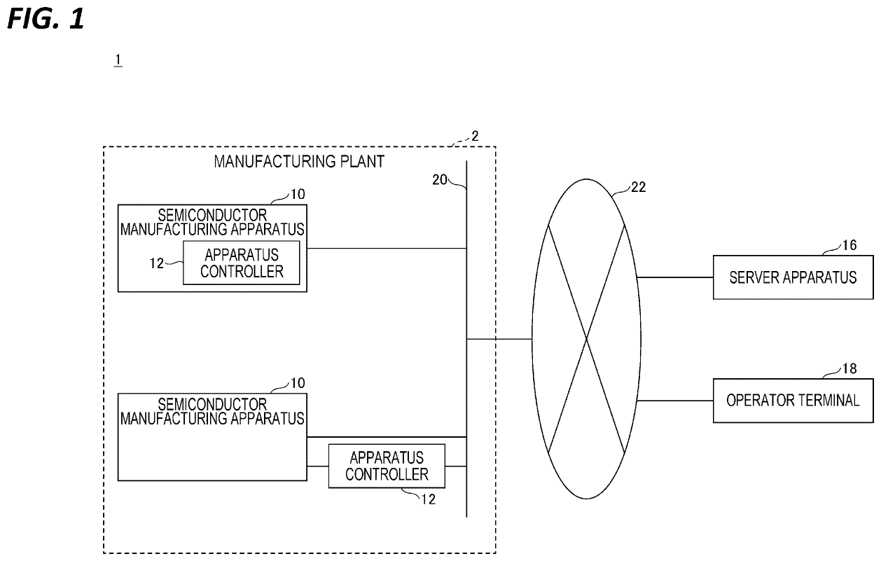

FIG. 1 is a configuration diagram illustrating an example of a semiconductor manufacturing system 1 according to the present embodiment. The semiconductor manufacturing system 1 of FIG. 1 includes a semiconductor manufacturing apparatus 10, an apparatus controller 12, a server apparatus 16, and an operator terminal 18. The semiconductor manufacturing apparatus 10 and the apparatus controller 12 are installed in a manufacturing plant 2. The server apparatus 16 and the operator terminal 18 may be installed either inside or outside the manufacturing plant 2. The operator terminal 18 is an information processing terminal such as a Personal Computer (PC) or a smartphone, which is operated by an operator such as an equipment manager in charge of the semiconductor manufacturing apparatus 10 installed in the manufacturing plant 2.

The semiconductor manufacturing apparatus 10, apparatus controller 12, server apparatus 16, and operator terminal 18 of FIG. 1 are communicatively connected via networks 20 and 22 such as the Internet or a Local Area Network (LAN).

The semiconductor manufacturing apparatus 10 is an apparatus that performs a process such as film formation, etching, or ashing for processing, for example, a semiconductor wafer (hereinafter simply referred to as “wafer”). The semiconductor manufacturing apparatus 10 is, for example, a substrate processing apparatus, a heat treatment apparatus, or a film forming apparatus, among others. The semiconductor manufacturing apparatus 10 receives, for example, recipes from the apparatus controller 12 and executes the recipes to perform a process. A recipe is a control command that combines settings for various categories such as temperature, gas, pressure, plasma, and mechanics.

The semiconductor manufacturing apparatus 10 is equipped with multiple sensors such as a temperature sensor for measuring a temperature and a pressure sensor for measuring a pressure. Further, the semiconductor manufacturing apparatus 10 is equipped with an actuator in which a power source is combined with components to perform a mechanical operation.

The apparatus controller 12 functions as a human-machine interface that receives instructions related to the semiconductor manufacturing apparatus 10 from the operator and provides information about the semiconductor manufacturing apparatus 10 to the operator. The apparatus controller 12 also receives sensor data output from the multiple sensors equipped in the semiconductor manufacturing apparatus 10. The apparatus controller 12 may perform, for example, anomaly detection or anomaly prediction for the semiconductor manufacturing apparatus 10.

The apparatus controller 12 is provided for each semiconductor manufacturing apparatus 10 in FIG. 1, but may be provided to manage multiple semiconductor manufacturing apparatuses 10. The apparatus controller 12 may be provided either inside or outside a housing of the semiconductor manufacturing apparatus 10.

The server apparatus 16 may receive sensor data output from the multiple sensors equipped in the semiconductor manufacturing apparatus 10, and may save it as a process log each time a process is performed (for each Run).

The server apparatus 16 may save, for example, information about multiple semiconductor manufacturing apparatuses 10 in one or more manufacturing plants 2 (such as recipes of processes performed by the semiconductor manufacturing apparatuses 10, and sensor data and results data obtained when processes are performed by recipe execution) as a process log for each Run.

The apparatus controller 12 and the server apparatus 16 may display information about the semiconductor manufacturing apparatus 10 on the operator terminal 18, or may notify the operator of the operator terminal 18 by e-mail or other electronic communication methods. Further, at least one of the apparatus controller 12, the server apparatus 16, and the operator terminal 18 has a function of editing a recipe to be executed by the semiconductor manufacturing apparatus 10. The apparatus controller 12, the server apparatus 16, and the operator terminal 18 of FIG. 1 are examples of information processing apparatuses according to the present embodiment.

In addition, it goes without saying that the semiconductor manufacturing system 1 illustrated in FIG. 1 is merely an example, and there are various system configuration examples depending on the application and purpose thereof. The classification of apparatuses such as the apparatus controller 12 and the server apparatus 16 in FIG. 1 is also merely an example. For example, various configurations are possible, including an integrated configuration of the apparatus controller 12 and the server apparatus 16 or a more subdivided configuration.

### Hardware Configuration

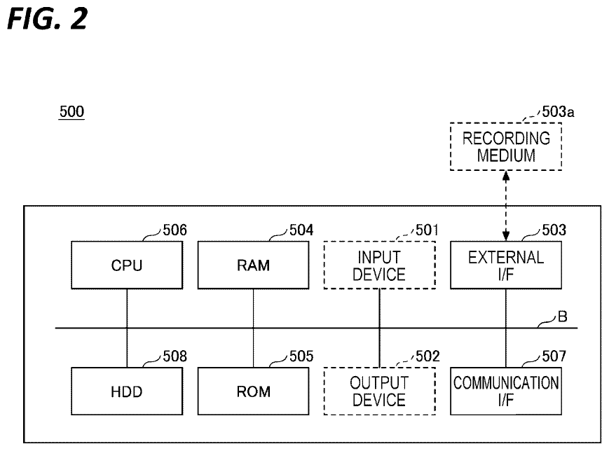

The apparatus controller 12, the server apparatus 16, and the operator terminal 18 illustrated in FIG. 1 may be realized, for example, using a computer with a hardware configuration illustrated in FIG. 2. FIG. 2 is a hardware configuration diagram illustrating an example of a computer 500.

The computer 500 of FIG. 2 includes various components such as an input device 501, output device 502, external interface (I/F) 503, Random Access Memory (RAM) 504, Read Only Memory (ROM) 505, Central Processing Unit (CPU) 506, communication I/F 507, and Hard Disk Drive (HDD) 508, each of which is interconnected via a bus B. The input device 501 and output device 502 may be connected and used as needed.

The input device 501 is, for example, a keyboard, a mouse, or a touch panel, and is used to input operation signals by the operator. The output device 502 is, for example, a display, and is used to display the results of processing by the computer 500. The communication I/F 507 serves as an interface that connects the computer 500 to the networks 20 and 22 illustrated in FIG. 1. The HDD 508 is an example of a non-volatile storage device that stores programs and data.

The external I/F 503 is an interface for an external device. The computer 500 may read information from a recording medium 503a such as a Secure Digital (SD) memory card via the external I/F 503. The external I/F 503 may also write information to the recording medium 503a such as an SD memory card via the external I/F 503.

The ROM 505 is an example of a non-volatile semiconductor memory (storage device) in which programs and data are stored. The RAM 504 is an example of a volatile semiconductor memory (storage device) used to temporarily hold programs and data. The CPU 506 is an operational device that reads programs and data from a storage device such as the ROM 505 or the HDD 508 and loads them onto the RAM 504 to execute a process, thereby implementing the overall control and functions of the computer 500.

The apparatus controller 12, the server apparatus 16, and the operator terminal 18 of the semiconductor manufacturing system 1 illustrated in FIG. 1 will implement various functions, which will be described later, by executing programs on the computer 500 illustrated in FIG. 2.

### Functional Configuration

In the following, an example will be described, in which an information processing apparatus for editing a recipe to be executed by the semiconductor manufacturing apparatus 10 is the apparatus controller 12. In addition, the information processing apparatus for editing the recipe to be executed by the semiconductor manufacturing apparatus 10 may also be the server apparatus 16 or the operator terminal 18.

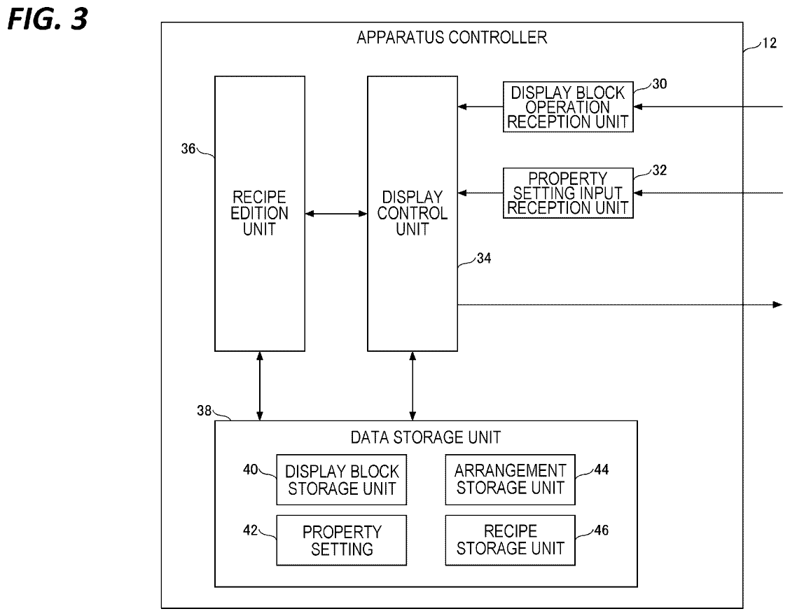

The apparatus controller 12 of the semiconductor manufacturing system 1 according to the present embodiment is realized, for example, by functional blocks illustrated in FIG. 3. FIG. 3 is a functional block diagram illustrating an example of the apparatus controller 12 according to the present embodiment. In addition, unnecessary configurations for the description of the present embodiment are omitted from the functional block diagram of FIG. 3.

The apparatus controller 12 realizes a display block operation reception unit 30, a property setting input reception unit 32, a display control unit 34, a recipe edition unit 36, and a data storage 38 by executing programs for the apparatus controller 12. The data storage 38 includes a display block storage 40, a property setting storage 42, an arrangement storage 44, and a recipe storage 46.

The display block operation reception unit 30 receives an input of a time during which the category setting continues by the operator's operation of arranging a plurality of display blocks on a screen, the display blocks visually indicating the setting of at least one of a plurality of categories included in a recipe. Details of the functionality of the display block operation reception unit 30 will be described later.

The property setting input reception unit 32 receives an input of a setting value of a setting item included in the category setting for each display block arranged on the screen from the operator. The input of the setting value of the setting item included in the category setting is a property setting input. Details of the functionality of the property setting input reception unit 32 will be described later.

The display control unit 34 causes the output device 502, such as a display, to display a screen for the operator to edit the recipe. Details of the screen for the operator to edit the recipe will be described later.

The recipe edition unit 36 edits a recipe by organizing steps, each step (minimum unit) made up of a combination of all setting items with assigned setting values and a time during which the setting continues, and arranging these steps in sequence, based on the time during which the category setting continues and the input of the setting value of the setting item. Details of the functionality of the recipe edition unit 36 will be described later.

The data storage 38 stores various data used by the display control unit 34 and the recipe edition unit 36. The display block storage 40 of the data storage 38 stores data on display blocks available for use by the operator. The property setting storage 42 stores data on a property setting input by the operator for each display block. The arrangement storage 44 stores data on the arrangement of the display blocks displayed on the screen by the operator's operation. The recipe storage 46 stores data on a recipe edited based on the arrangement of the display blocks displayed on the screen by the operator's operation and the property setting input by the operator for each display block.

The semiconductor manufacturing apparatus 10 according to the present embodiment executes a recipe stored in the recipe storage 46 to perform a process. The recipe executed by the semiconductor manufacturing apparatus 10 divides the process into sections, called steps, as the minimum unit. For each step, setting values are assigned to setting items of various categories such as temperature, gas, pressure, plasma, and mechanics.

A step is made up of a combination of all setting items with assigned setting values of various categories, such as temperature, gas, pressure, plasma, and mechanics, and a time during which the setting continues. The semiconductor manufacturing apparatus 10 performs a process by executing a recipe in which steps are arranged in sequence.

### Overview of Present Embodiment

### Recipe

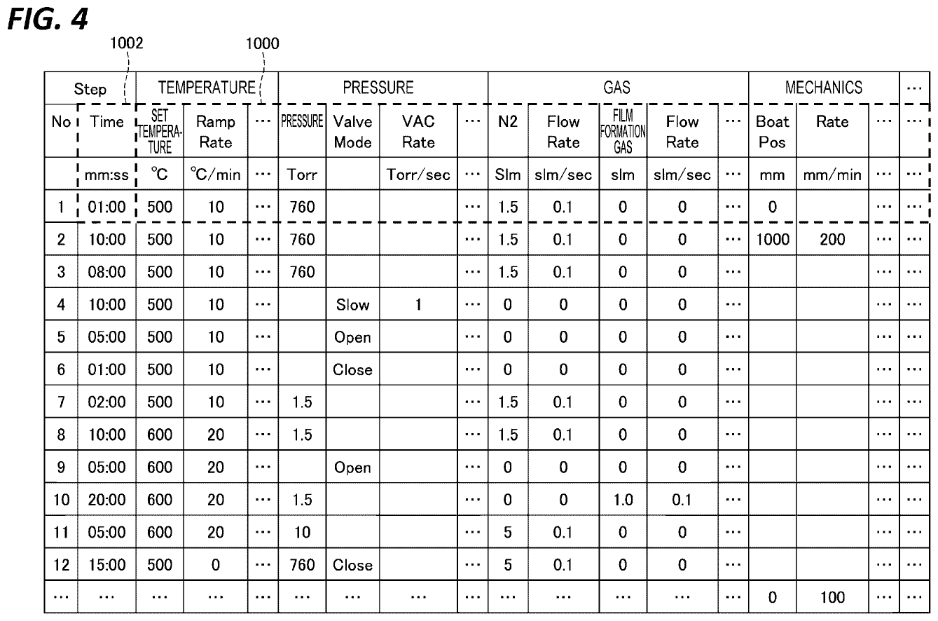

FIG. 4 is a configuration diagram illustrating an example of a recipe to be executed by the semiconductor manufacturing apparatus 10. As illustrated in FIG. 4, the recipe is divided into steps as the basic unit. In FIG. 4, each step is made up of a combination 1000 of all setting items with assigned setting values of various categories such as temperature, pressure, gas, and mechanics, and a time 1002 during which the setting continues.

In recent years, as the semiconductor manufacturing apparatus 10 has advanced in miniaturization, the number of actuators and sensors has increased. Consequently, the number of setting items in the recipe of FIG. 4 has also increased, making the editing of the recipe to be executed by the semiconductor manufacturing apparatus 10 more complex. For example, the setting items in the recipe of FIG. 4 are simplified compared to an actual recipe.

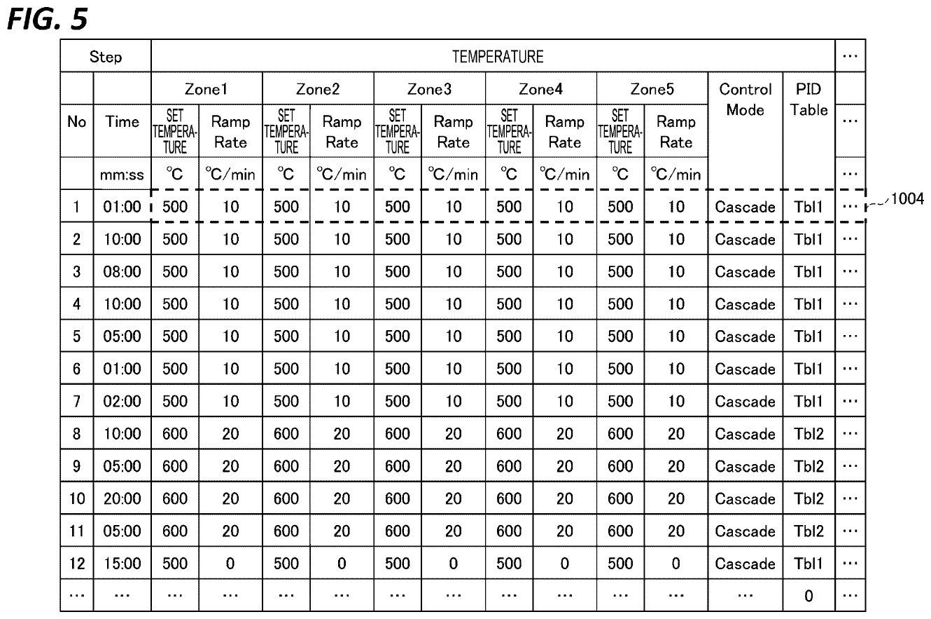

For example, as illustrated in FIG. 5, setting items for a temperature category include the set temperatures and ramp rates of multiple zones, a control mode, and a PID table, all of which require the setting of setting values 1004 for every step. FIG. 5 is a configuration diagram illustrating an example of setting items for a temperature category.

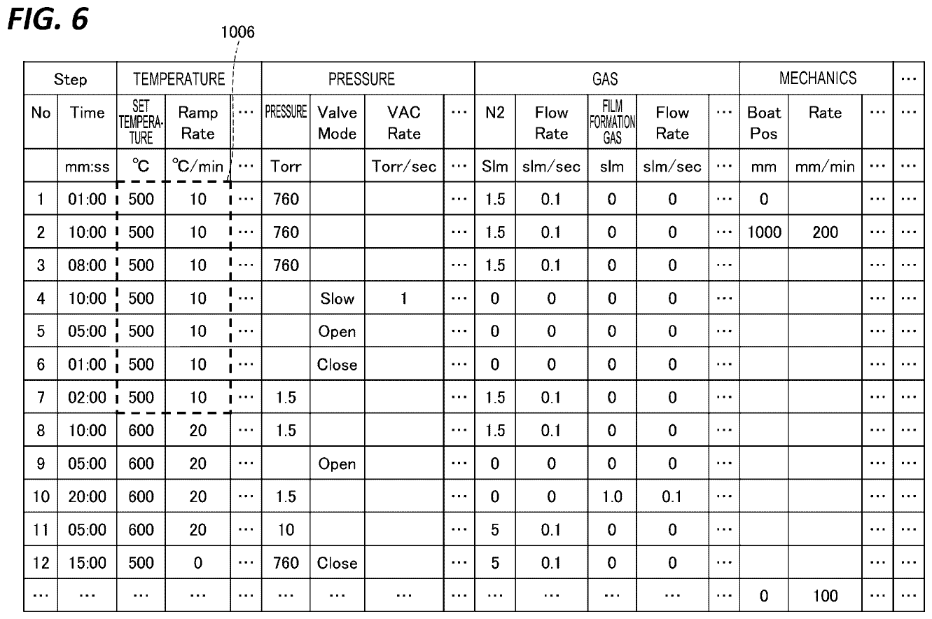

Further, since a step is made up of a combination of all setting items with assigned setting values of various categories and a time during which the setting continues, any single change in the setting values of other categories requires the same setting values 1006 to be continuously input, as illustrated in FIG. 6. FIG. 6 is a configuration diagram illustrating an example of a recipe in which the same setting values are input.

In this way, editing the recipe to be executed by the semiconductor manufacturing apparatus 10 has become increasingly burdensome for the operator due to the growing number of steps caused by the increasing combinations of setting items.

Further, with the recent improvement in the performance of artificial intelligence (AI), AI may calculate (infer) optimal setting values of setting items included in a recipe, even for continuously varying setting values. However, since the recipe requires inputting setting values and rates 1010 for setting items of various categories on a step-by-step basis, it may basically only respond in discrete steps.

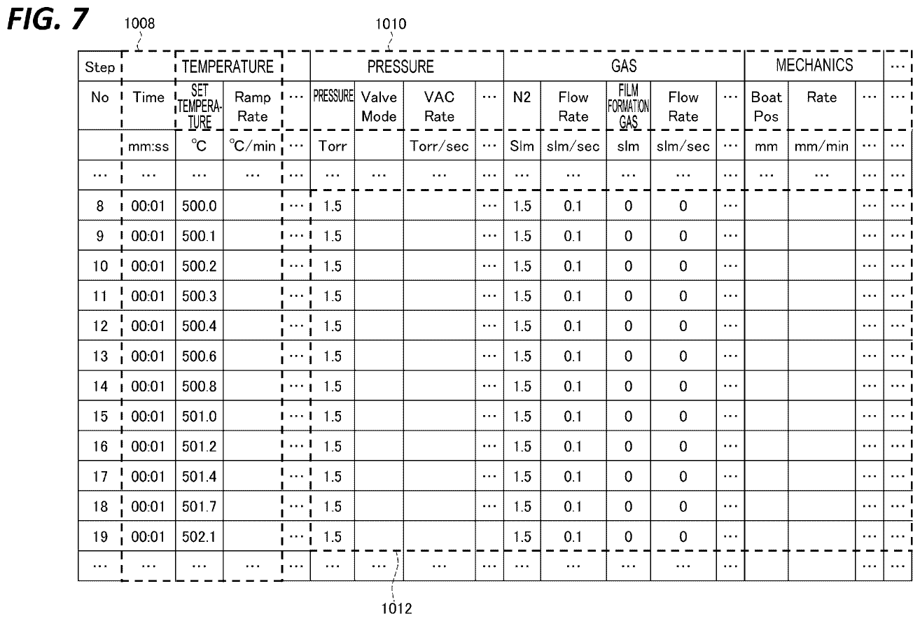

For example, if continuously varying setting values calculated by AI are to be incorporated into a recipe, the recipe needs to be divided into steps with the minimum time unit (e.g., 1 second), as illustrated in FIG. 7. FIG. 7 is a configuration diagram illustrating an example of a recipe in which continuously varying setting values are input. Consequently, setting values 1012 of setting items that do not vary continuously need to still be input even though they remain the same.

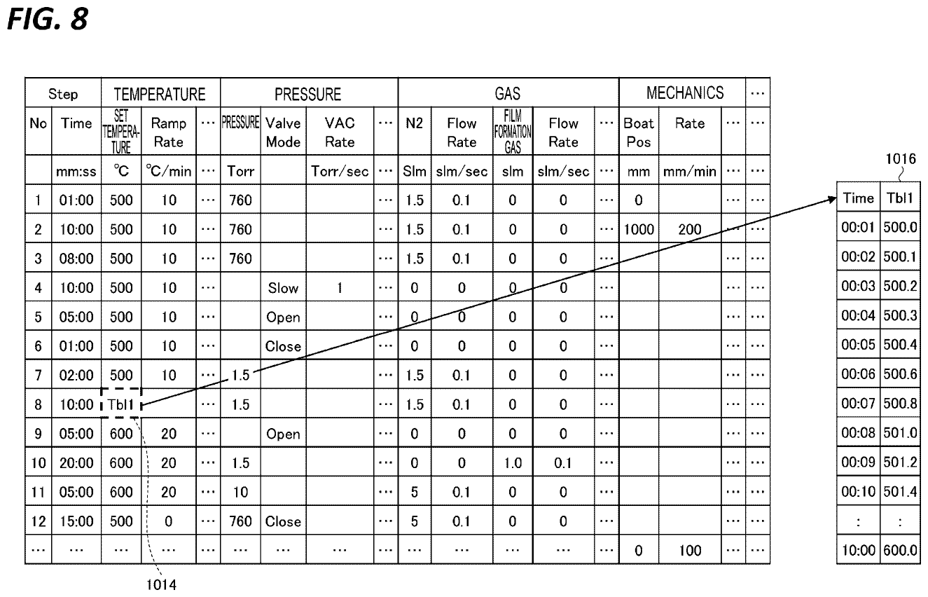

Further, when incorporating continuously varying setting values into a recipe, as illustrated in FIG. 8, it is also conceivable to assign the continuously varying setting values in a separate table 1016 and refer to the table 1016. FIG. 8 is a configuration diagram illustrating an example of a recipe in which continuously varying setting values are input.

However, the step time is a common time for all setting items within that step. Therefore, it is necessary to align the step time with a time during which the setting values, assigned to the table 1016, vary continuously.

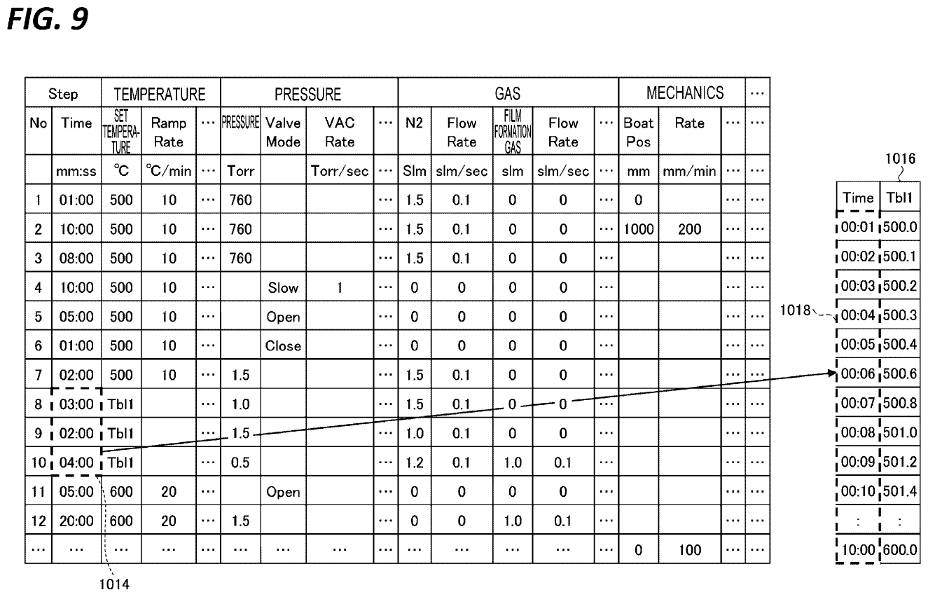

Furthermore, as illustrated in FIG. 9, when attempting to change setting values for other categories at different step times while the temperature is varying due to continuously varying setting values, time misalignment may occur. FIG. 9 is a configuration diagram illustrating an example of a recipe in which while the temperature is varying due to continuously varying setting values, setting values of other categories are changed at different step times. For example, in FIG. 9, a time 1014 for pressure and gas setting items is not aligned with a time 1018 set in the table 1016. This arises because a common time is used across all categories.

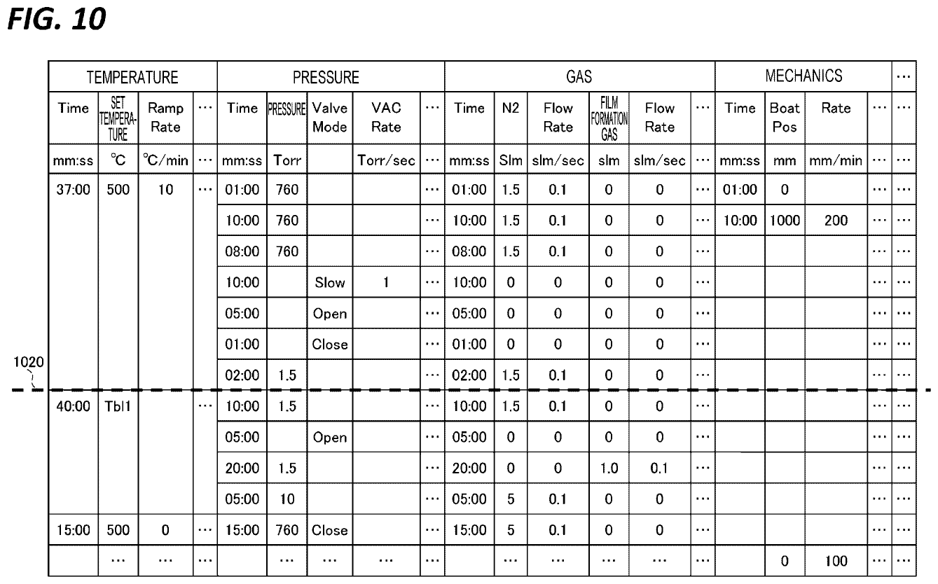

To address this issue, it is necessary to assign an individual step time to each category, as illustrated in FIG. 10. FIG. 10 is a configuration diagram illustrating an example of a recipe in which each category has its own step time. In the example of FIG. 10, for example, the operator needs to adjust the step time of each category to align a timing 1020 across different categories.

Accordingly, in the semiconductor manufacturing system 1 of the present embodiment, the timing of switching between setting values of setting items for each category is displayed in a graphical manner as described later, for example, in a Computer-Aided Design (CAD) tool where the operator edits a recipe. This allows for the operator to easily align the timing of switching between setting values of setting items for each category, making recipe editing easier in the semiconductor manufacturing system 1 according to the present embodiment.

### Recipe Editing Screen

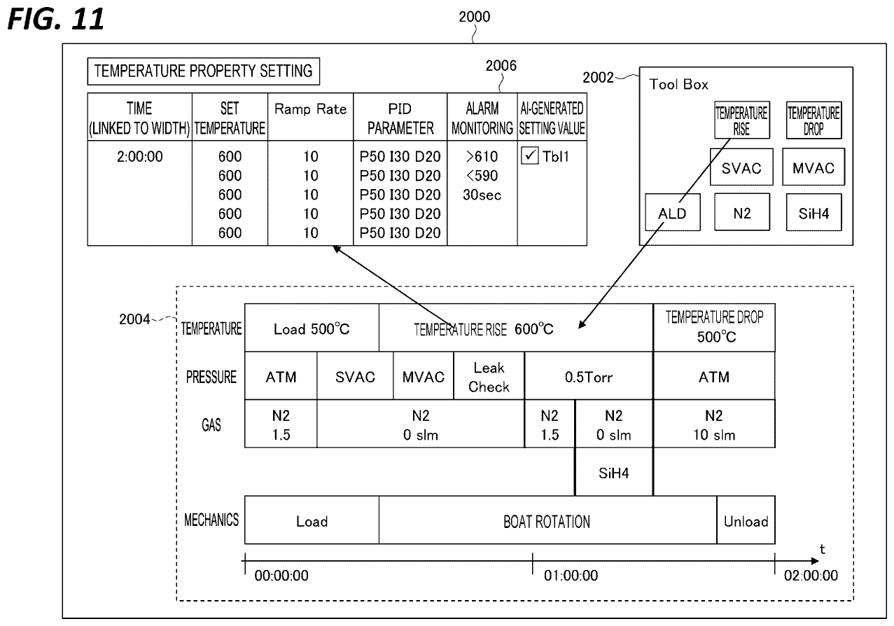

The apparatus controller 12 according to the present embodiment displays a recipe editing screen 2000, for example, as illustrated in FIG. 11, to make it easier for the operator to edit a recipe. FIG. 11 is an image diagram illustrating an example of the recipe editing screen 2000 according to the present embodiment.

In the recipe editing screen 2000, a plurality of display blocks, which visually indicate the setting of at least one of a plurality of categories included in a recipe, are prepared in a tool box 2002. The display blocks may be displayed in a visually distinguished manner, for example, by using different colors for each category, to make them easily identifiable to the operator.

The display block to be used may be moved and arranged in a recipe editing area 2004 by the operator's operation such as drag-and-drop. The width of the display block arranged in the recipe editing area 2004 represents time. The operator may move and arrange the plurality of display blocks from the tool box 2002 into the recipe editing area 2004 as illustrated in FIG. 11, for example.

For example, taking the temperature category setting illustrated in the recipe editing area 2004 of FIG. 11 as an example, the operator moves “Load,” “Temperature Rise,” and “Temperature drop” display blocks selected from the tool box 2002 into the recipe editing area 2004 to arrange them horizontally in a connected sequence. A time during which the temperature category setting indicated by the display block is linked to the width of the display block, making it easy for the operator to recognize.

Further, the operator may select the display block in the recipe editing area 2004 by clicking or performing other operations, which brings up the display of a property setting area 2006. The property setting area 2006 receives an input of a setting value of a setting item included in the category setting indicated by the display block from the operator.

For example, the property setting area 2006 of FIG. 11 receives, from the operator, an input of setting values for “Set Temperature,” “Ramp Rate,” “PID Parameter,” “Alarm Monitoring,” and “AI-Generated Setting Value” setting items included in the temperature category setting indicated by the “Temperature Rise” display block in the recipe editing area 2004. Further, for the “AI-Generated Setting Value” setting item, a separate table (e.g., table 1016 illustrated in FIG. 8) where AI-calculated continuously varying setting values are assigned may be specified. In addition, the “Temperature Rise to 600° C.” display block in the recipe editing area 2004 of FIG. 11 additionally displays a representative temperature “600° C.” assigned to the “Set Temperature” setting item in the property setting area 2006.

In the recipe editing screen 2000 of FIG. 11, property setting may be made for each display block, which allows different category settings to be represented as a single setting even if they vary, eliminating the need to repeatedly input the same setting values.

Since the width of the display block represents time in the recipe editing screen 2000 of FIG. 11, the timing of switching between setting values of setting items for each category may be visually aligned. This makes it easier for the operator to align the timing of switching between setting values of setting items for each category, making recipe editing easier.

Further, the recipe editing screen 2000 of FIG. 11 removes the step-based concept and allows setting for each category to be made independently. Therefore, the recipe editing screen 2000 of FIG. 11 presents minimum necessary information, making it easier for the operator to understand.

### Example of Display Block Type

Examples of display block types include a temperature block that visually indicates temperature category setting, a pressure block that visually indicates pressure category setting, a gas block that visually indicates gas category setting, a mechanical boat rotation block and mechanical boat ELV block that visually indicate mechanical category setting, and a special film formation block that visually indicates special film formation setting.

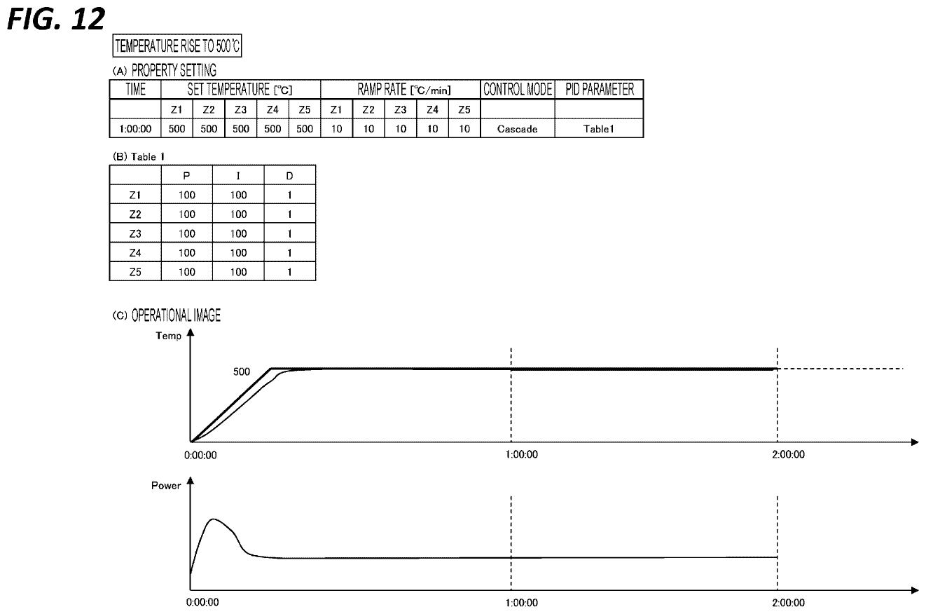

FIG. 12 is a diagram illustrating a “Temperature Rise to 500° C.” display block as an example of a temperature block. Part (A) of FIG. 12 illustrates an example of property setting for the “Temperature Rise” display block with a representative temperature of “500° C.” In part (A) of FIG. 12, an external table “Table 1” for reference is assigned to a “PID Parameter” setting item. Part (A) of FIG. 12 illustrates an example of “Table 1” in which setting values of the “PID Parameter” setting item are assigned. Part (C) of FIG. 12 illustrates an example of an operational image in the case of property setting illustrated in parts (A) and (B) FIG. 12.

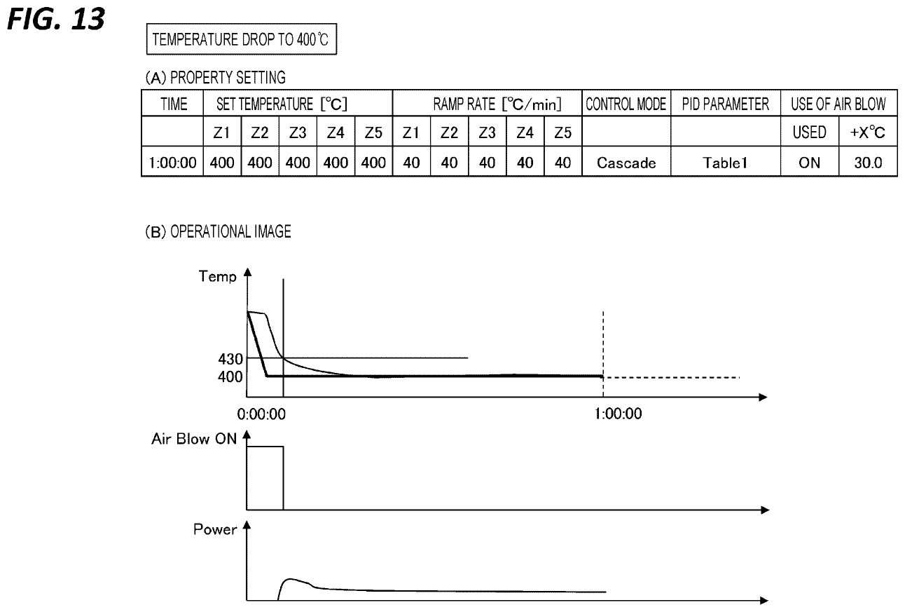

FIG. 13 is a diagram illustrating a “Temperature Drop to 400° C.” display block as an example of a temperature block. Part (A) of FIG. 13 illustrates an example of property setting for the “Temperature Drop” display block with a representative temperature of “400° C.” In part (A) of FIG. 13, an external table “Table 1” for reference is assigned to a “PID parameter” setting item. “Table 1” in which setting values of the “PID Parameter” setting item are assigned is omitted. Part (B) of FIG. 13 illustrates an example of an operational image in the case of property setting illustrated in part (A) of FIG. 13. Part (B) of FIG. 13 illustrates an operational image in which high-speed cooling using an air blow is performed up to 430° C., followed by stabilization at 400° C. through cascade control.

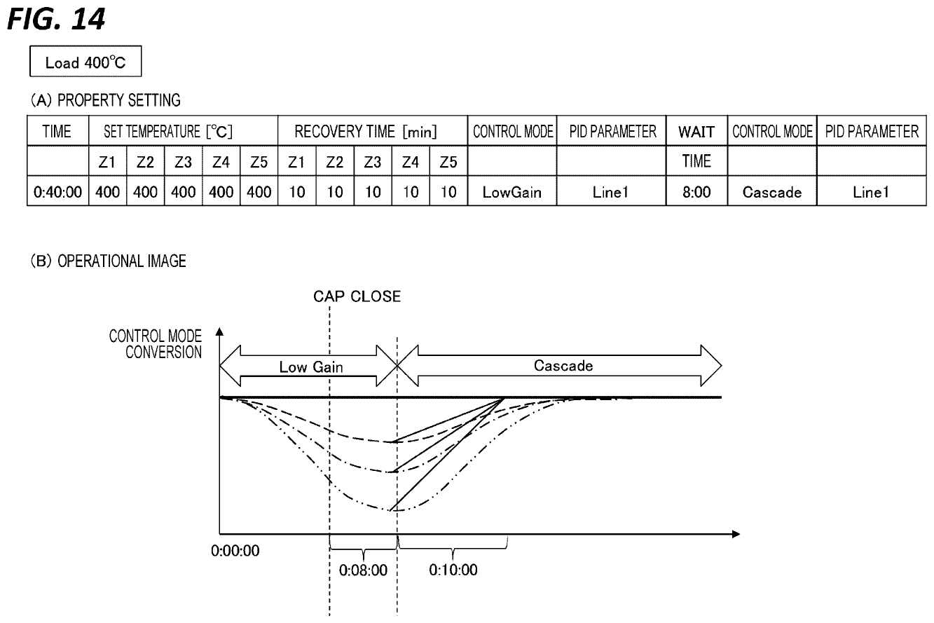

FIG. 14 is a diagram illustrating a “Load at 400° C.” display block as an example of a temperature block. Part (A) of FIG. 14 illustrates an example of property setting for the “Load” display block with a representative temperature of “400° C.” Part (B) of FIG. 14 illustrates an example of an operational image in the case of property setting illustrated in Part (A) of FIG. 14.

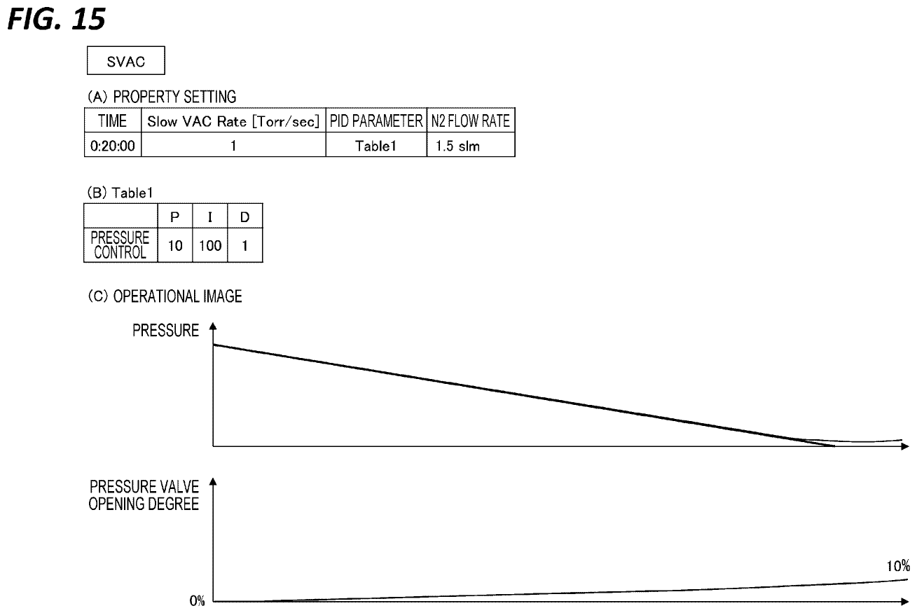

FIG. 15 is a diagram illustrating an “SVAC” display block as an example of a pressure block. Part (A) of FIG. 15 illustrates an example of property setting for a vacuum creation display block. In part (A) of FIG. 15, an external table “Table 1” for reference is assigned to a “PID parameter” setting item. Part (B) of FIG. 15 illustrates an example of “Table 1” in which setting value of the “PID Parameter” setting item are assigned. Part (C) of FIG. 15 illustrates an example of an operational image in the case of property setting illustrated in parts (A) and (B) FIG. 15.

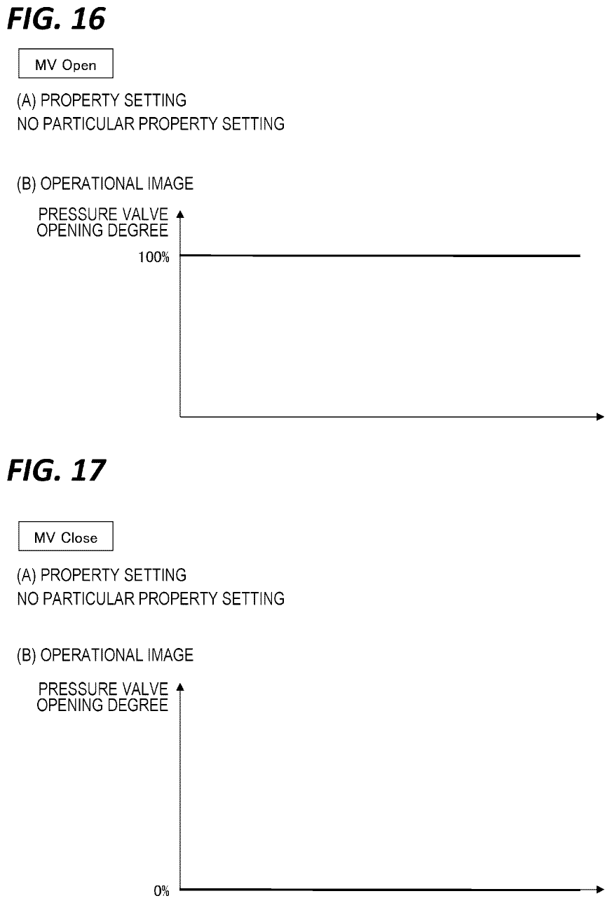

FIG. 16 is a diagram illustrating an “MV Open” display block as an example of a pressure block. Part (A) of FIG. 16 illustrates that there is no particular property setting for the “MV Open” display block. Part (B) of FIG. 16 illustrates an example of an operational image in the case of the “MV Open” display block.

FIG. 17 is a diagram illustrating an “MV Close” display block as an example of a pressure block. Part (A) of FIG. 17 illustrates that there is no particular property setting for the “MV Close” display block. Part (B) of FIG. 17 illustrates an example of an operational image in the case of the “MV Close” display block.

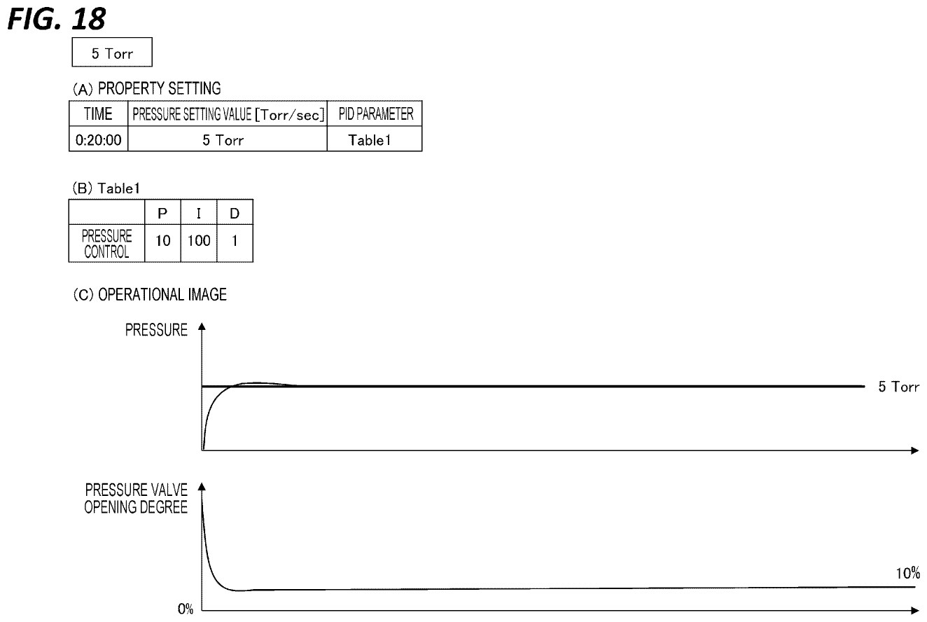

FIG. 18 is a diagram illustrating a “Pressure Control” display block as an example of a pressure block. Part (A) of FIG. 18 illustrates an example of property setting for the “Pressure Control” display block with a pressure setting value of “5 Torr.” In part (A) of FIG. 18, an external table “Table 1” for reference is assigned to a “PID parameter” setting item. Part (B) of FIG. 18 illustrates an example of “Table 1” in which setting value of the “PID Parameter” setting item are assigned. Part (C) of FIG. 18 illustrates an example of an operational image in the case of property setting illustrated in parts (A) and (B) of FIG. 18. The “Pressure Control” display block illustrated in FIG. 18 displays, for example, the setting value “5 Torr,” which is assigned to a “Pressure Setting Value” setting item of property setting in part (A) of FIG. 18.

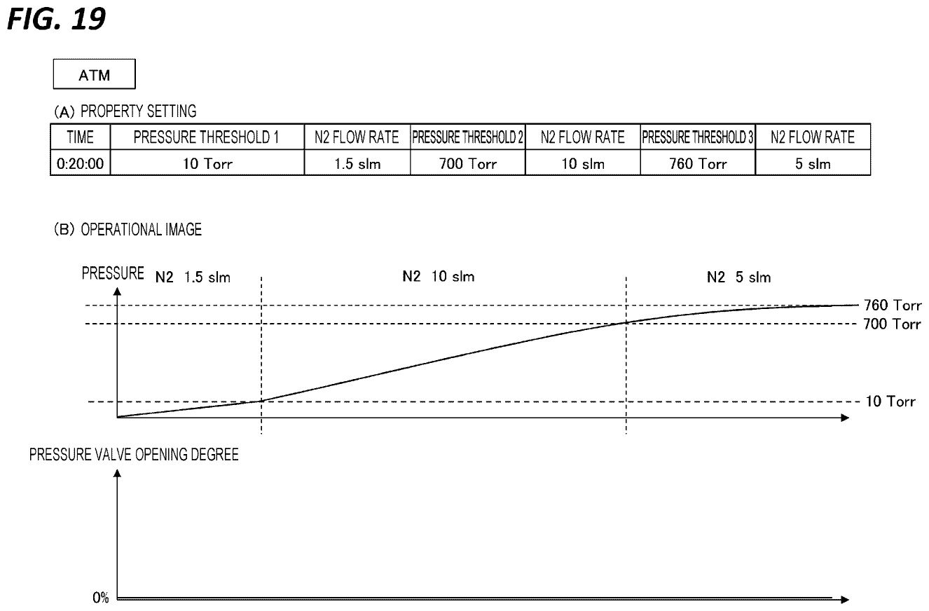

FIG. 19 is a diagram illustrating an “ATM” display block as an example of a pressure block. Part (A) of FIG. 19 illustrates an example of property setting for the “ATM” display block, which is used to restore atmospheric pressure by flowing a gas. Part (B) of FIG. 19 illustrates an example of an operational image in the case of property setting illustrated in Part (A) of FIG. 19.

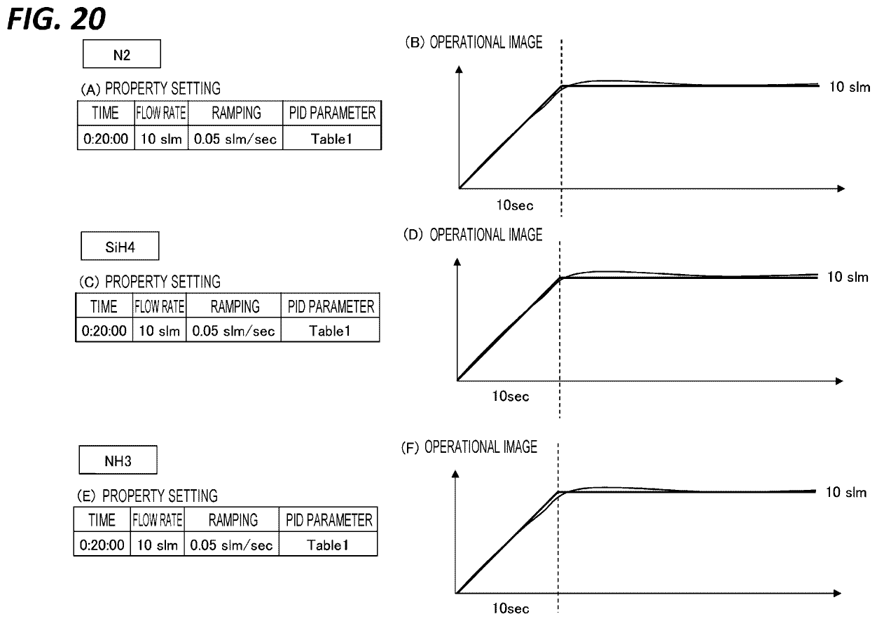

FIG. 20 is a diagram illustrating “N2,” “SiH4,” and “NH3” display blocks as examples of gas blocks.

Part (A) of FIG. 20 illustrates an example of property setting for an “N2” gas display block. In part (A) of FIG. 20, an external table “Table 1” for reference is assigned to a “PID parameter” setting item. “Table 1” in which setting values of the “PID Parameter” setting item are assigned is omitted. Part (B) of FIG. 20 illustrates an example of an operational image of “N2” gas in the case of property setting illustrated in part (A) of FIG. 20.

Part (C) of FIG. 20 illustrates an example of property setting for a “SiH4” gas display block. In part (C) of FIG. 20, an external table “Table 1” for reference is assigned to a “PID parameter” setting item. “Table 1” in which setting values of the “PID Parameter” setting item are assigned is omitted. Part (D) of FIG. 20 illustrates an example of an operational image of “SiH4” gas in the case of property setting illustrated in part (C) of FIG. 20.

Part (E) of FIG. 20 illustrates an example of property setting for an “NH3” gas display block. In part (E) of FIG. 20, an external table “Table 1” for reference is assigned to a “PID parameter” setting item. “Table 1” in which setting values of the “PID Parameter” setting item are assigned is omitted. Part (F) of FIG. 20 illustrates an example of an operational image of “NH3” gas in the case of property setting illustrated in part (E) of FIG. 20.

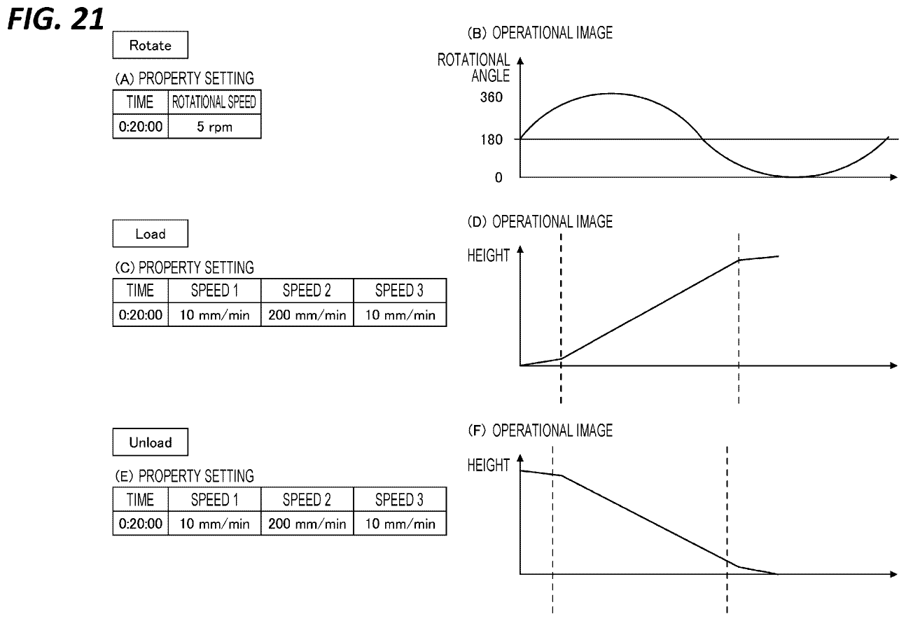

FIG. 21 is a diagram illustrating a “Rotate” display block as a mechanical boat rotation block, a “Load” display block as a mechanical boat ELV block, and an “Unload” display block as a mechanical boat ELV block.

Part (A) of FIG. 21 illustrates an example of property setting for the “Rotate” display block as a mechanical boat rotation block. Part (B) of FIG. 21 illustrates an example of an operational image of boat rotation in the case of property setting illustrated in part (A) of FIG. 21.

Part (C) of FIG. 21 illustrates an example of property setting for the “Load” display block as a mechanical boat ELV block. Part (D) of FIG. 21 illustrates an example of an operational image of raising (loading) a boat in the case of property setting illustrated in part (C) of FIG. 21.

Part (E) of FIG. 21 illustrates an example of property setting for the “Unload” display block as a mechanical boat ELV block. Part (F) of FIG. 21 illustrates an example of an operational image of lowering (unloading) a boat in the case of property setting illustrated in part (E) of FIG. 21.

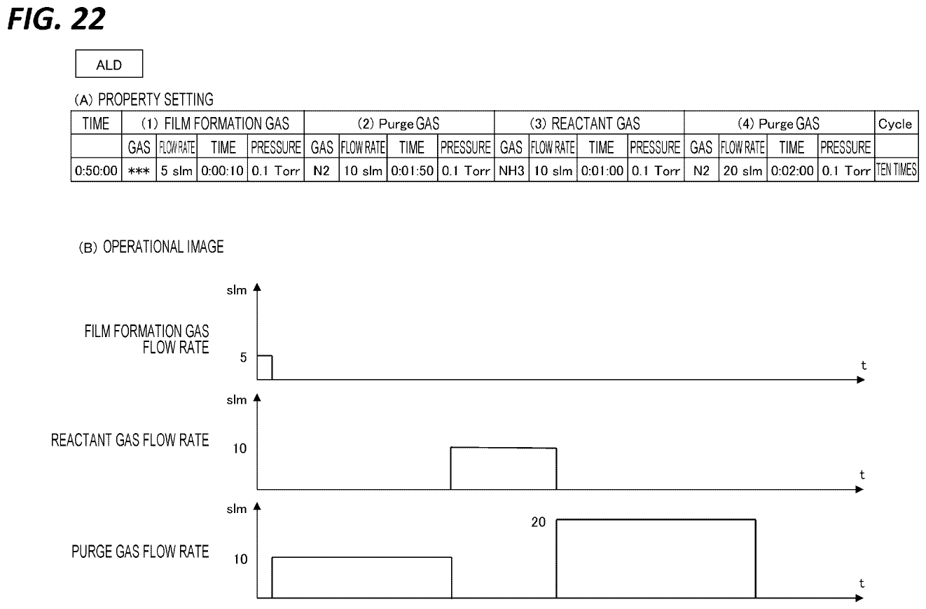

FIG. 22 is a diagram illustrating an “ALD” display block as an example of a special film formation block. Part (A) of FIG. 22 illustrates an example of property setting for the “ALD” display block, which is capable of handling continuous data combinations of multiple gases and pressures such as Atomic Layer Deposition (ALD). Part (B) of FIG. 22 illustrates an example of an operational image of a film formation gas flow rate, reactant gas flow rate, and purge gas flow rate in the case of property setting illustrated in part (A) of FIG. 22.

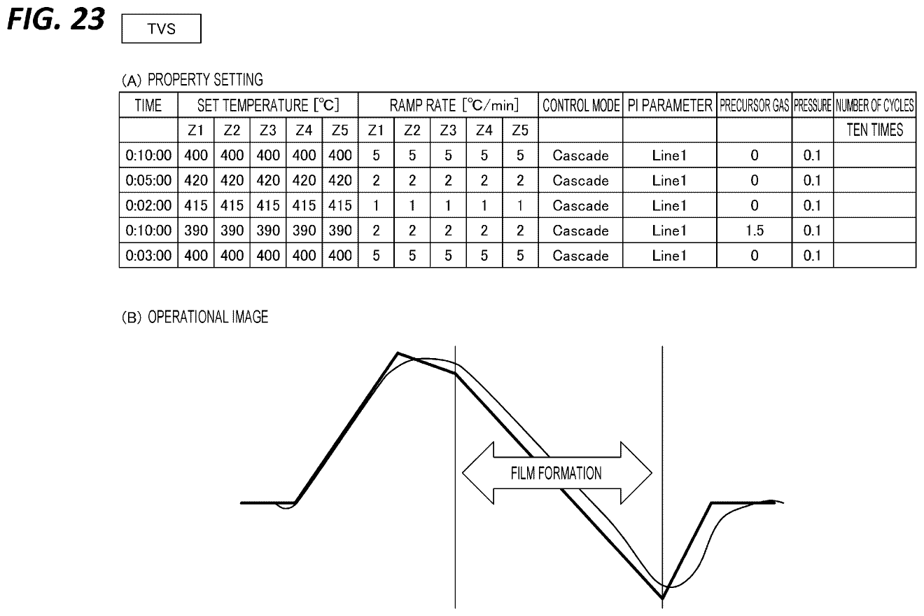

FIG. 23 is a diagram illustrating a “TVS” display block as an example of a special film formation block. Part (A) of FIG. 23 illustrates an example of property setting for the “TVS” display block, which is capable of handling even temperature drop during film formation such as TVS. Part (B) of FIG. 23 illustrates an example of an operational image of a temperature drop during film formation and a temperature rise outside of the film formation process in the case of property setting in part (A) of FIG. 23.

### Display Example of Recipe Editing Area

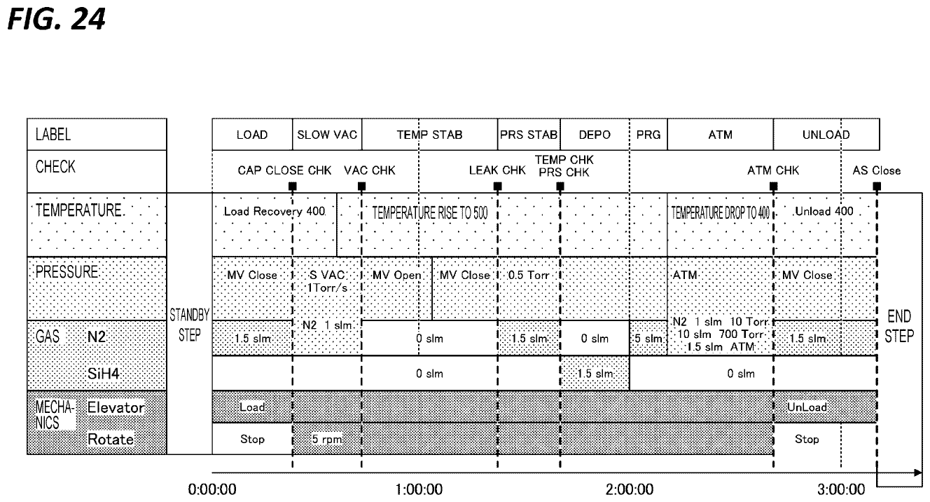

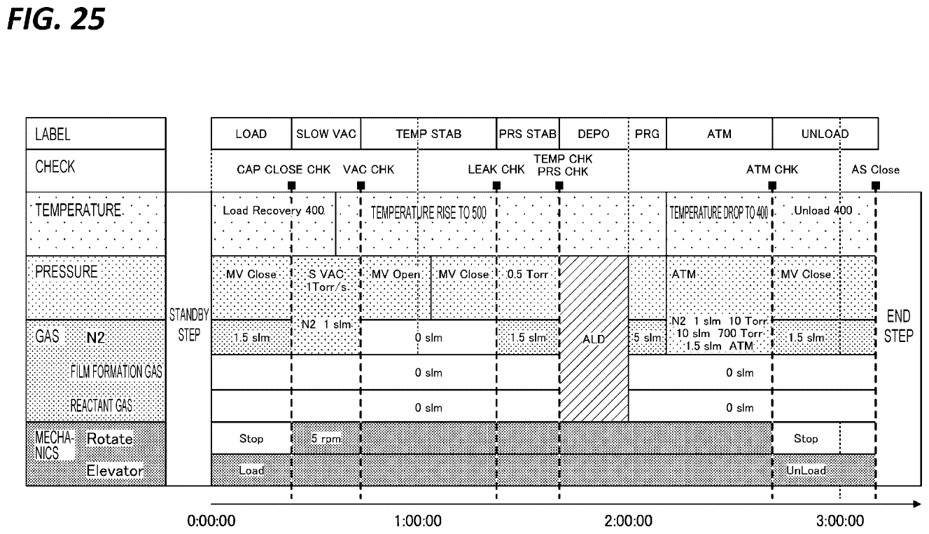

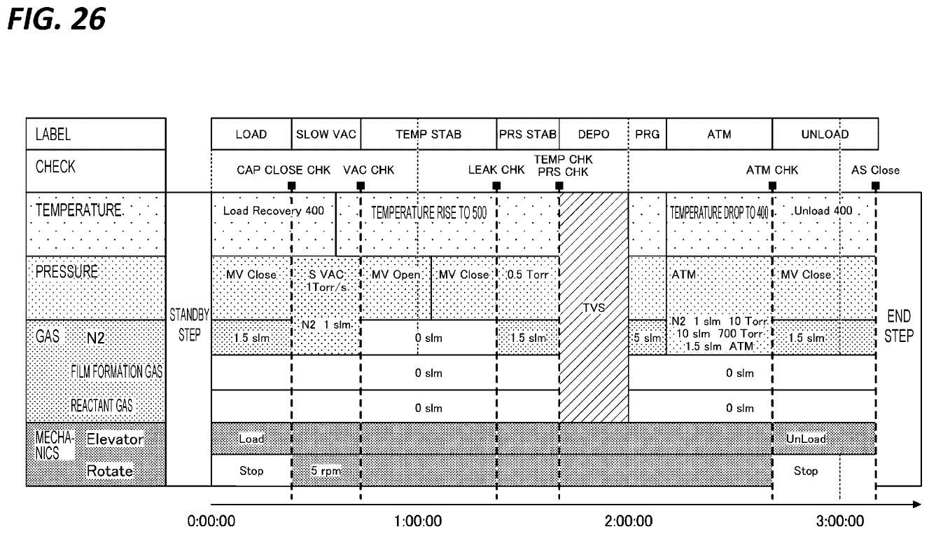

FIGS. 24 to 26 are explanatory diagrams illustrating an example of the recipe editing area 2004 where display blocks are arranged. In FIG. 24, an “ATM” display block is arranged, which visually indicates setting for both pressure and gas categories. In FIG. 25, an “ALD” display block is arranged, which visually indicates setting for both pressure and gas categories. Further, FIG. 26 includes a “TVS” display block, which visually indicates setting for temperature, pressure, and gas categories.

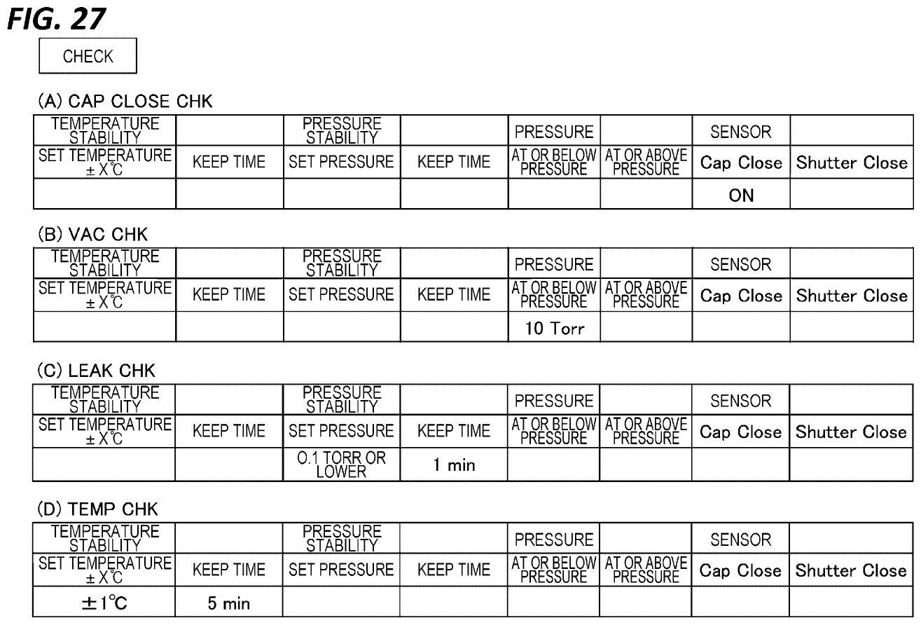

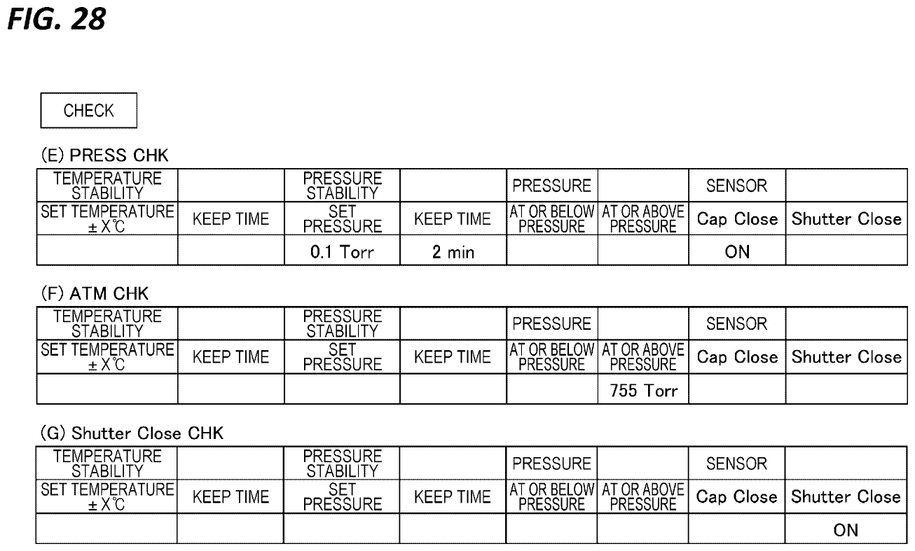

In the recipe editing area 2004 of FIGS. 24 to 26, dotted lines visually indicate setting for checks as illustrated in FIGS. 27 and 28. FIGS. 27 and 28 are diagrams illustrating setting for visually indicated checks in the recipe editing area 2004. Parts (A) to (D) of FIG. 27 and part (E) and (G) of FIG. 28 illustrate examples of property setting for various types of checks.

As illustrated in FIGS. 24 to 26, the operator may place dotted lines in the recipe editing area 2004 to visually indicate the check setting while being aware of the timing of the check, which enables easy property setting as illustrated in FIGS. 27 and 28.

### Conversion to Existing Recipe Structure

The recipe edition unit 36 edits a recipe with an existing recipe structure, which may be executed by the semiconductor manufacturing apparatus 10, based on the arrangement of display blocks in the recipe editing area 2004 and property setting input to the property setting area 2006.

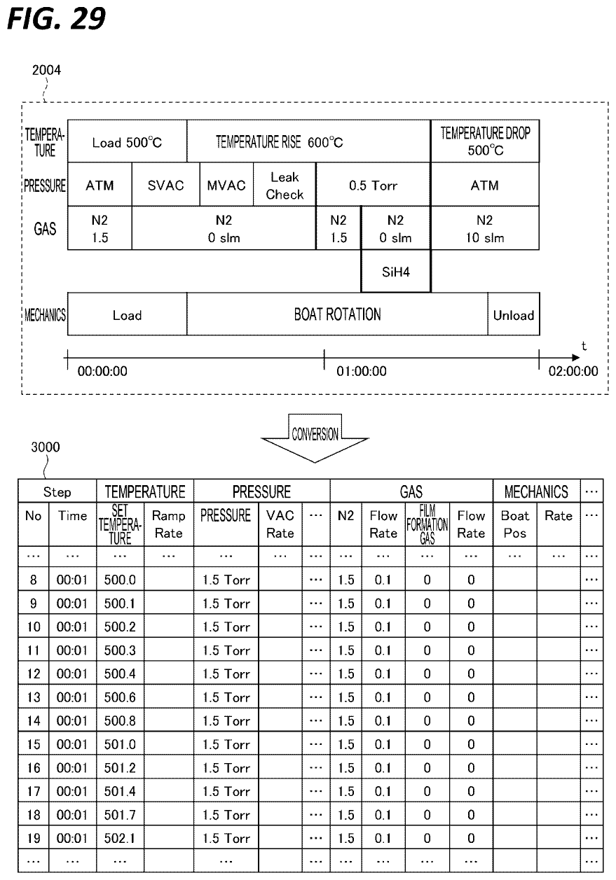

FIG. 29 is an image diagram illustrating an example of a process for editing a recipe 3000 with an existing recipe structure based on the arrangement of display blocks in the recipe editing area 2004 and property setting input to the property setting area 2006.

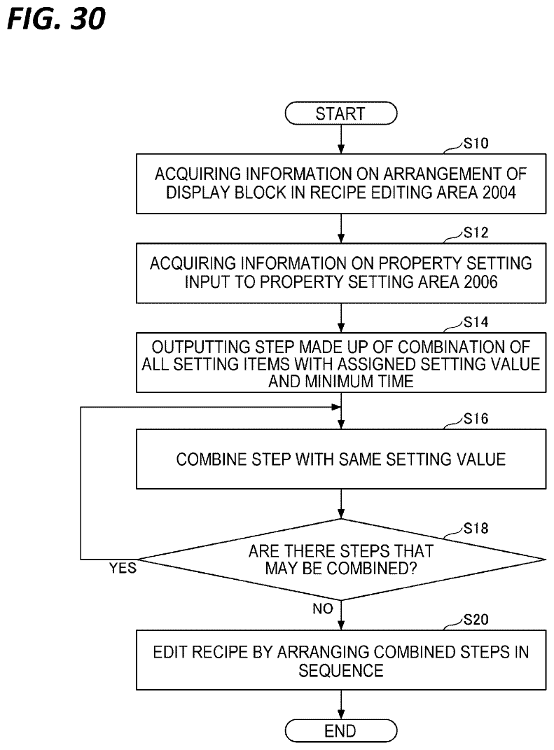

Since the recipe editing area 2004 does not have the step-based concept, the recipe edition unit 36 performs conversion to the recipe 3000 with an existing recipe structure, for example, using the procedure outlined in the flowchart of FIG. 30. FIG. 30 is a flowchart illustrating an example of a process for conversion to an existing recipe structure.

In step S10, the recipe edition unit 36 acquires information on the arrangement of display blocks in the recipe editing area 2004. The information on the arrangement of display blocks in the recipe editing area 2004 indicates a time during which setting of setting items continues.

In step S12, the recipe edition unit 36 acquires information on property setting input to the property setting area 2006. The information on the property setting input to the property setting area 2006 indicates input setting values for setting items.

In step S14, the recipe edition unit 36 outputs a step made up of a combination of all setting items with assigned setting values and the minimum time. The step output in step S14 is the minimum unit with the minimum time (e.g., 1 second), considering step combination in subsequent processing. Therefore, the step output in step S14 may include consecutive steps where all setting items have the same setting values.

In step S16, the recipe edition unit 36 repeats combining steps where all setting items have the same setting values until it is determined in step S18 that no further steps may be combined.

When it is determined in step S18 that no further steps may be combined, the recipe edition unit 36 edits the recipe 3000 with an existing recipe structure, which may be executed by the semiconductor manufacturing apparatus 10, by arranging the combined steps in sequence in step S20.

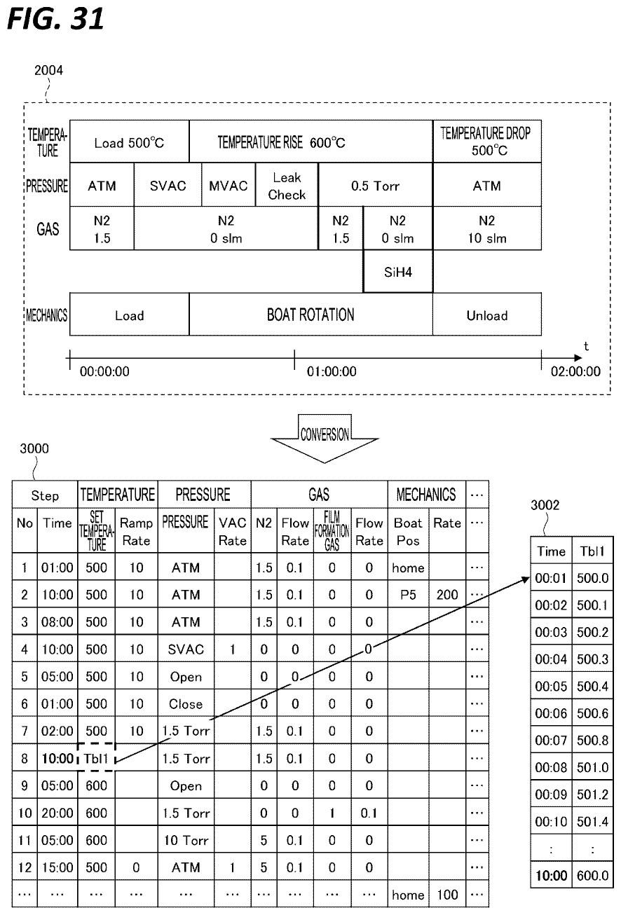

In addition, the recipe 3000 edited by the recipe edition unit 36 may refer to a table 3002 in which continuously varying setting values are assigned, as illustrated in FIG. 31.

The semiconductor manufacturing system 1 according to the present disclosure may provide a technique that allows the operator to more easily edit a recipe to be executed by the semiconductor manufacturing apparatus 10.

The semiconductor manufacturing apparatus 10 of the present disclosure may be applied to any type of apparatuses such as atomic layer deposition (ALD), capacitively coupled plasma (CCP), inductively coupled plasma (ICP), radial line slot antenna (RLSA), electron cyclotron resonance plasma (ECR), and helicon wave plasma (HWP) apparatuses. The semiconductor manufacturing apparatus 10 of the present disclosure may also be applied to a chemical vapor deposition (CVD) apparatus and an oxidation/annealing apparatus.

It goes without saying that the semiconductor manufacturing system 1 of the present disclosure is not limited to the configuration illustrated in FIG. 1, and various system configuration examples may be adopted depending on the application and purpose. The semiconductor manufacturing apparatus 10 of the present disclosure may be applied to any of a single-wafer apparatus that processes substrates one by one, a batch apparatus that processes multiple substrates at once, and a semi-batch apparatus. The processes performed by the semiconductor manufacturing apparatus 10 of the present disclosure may include, for example, film formation and etching, among others.

According to the present disclosure, it is possible to provide a technique that allows an operator to more easily edit recipes to be executed by a semiconductor manufacturing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
display block operation reception circuitry configured to receive, by an operation of an operator of arranging, on a screen, a plurality of display blocks visually indicating setting of at least one category among a plurality of categories included in a recipe to be executed by a semiconductor manufacturing apparatus, an input of a time during which the setting of the category continues;
property setting input reception circuitry configured to receive, from the operator, an input of a setting value of a setting item included in the setting of the category for each display block arranged on the screen; and
recipe edition circuitry configured to edit the recipe by sequentially arranging steps, each made up of a combination of all setting items set with the setting values and the time during which the setting continues, as a minimum unit, based on the time during which the setting of the category continues and the input of the setting value of the setting item.

2. The information processing apparatus according to claim 1, wherein the display block operation reception circuitry receive an operation of the operator of arranging, in a connected manner, the plurality of display blocks, each representing the time during which the setting of the category continues, by width.

3. The information processing apparatus according to claim 1, wherein the property setting input reception circuitry receive the input of the setting value from the operator through setting of a referenced table.

4. The information processing apparatus according to claim 1, wherein the recipe edition circuitry output, as the minimum unit, a step made up of a combination of all setting items set with the setting values and a time shorter than the time during which the setting continues, and then edits the recipe by sequentially arranging the steps after combining the steps with the same setting value.

5. The information processing apparatus according to claim 1, wherein the display blocks visually indicate at least one of setting of a temperature category, setting of a pressure category, setting of a gas category, setting of a mechanics category, and setting of special film formation included in the recipe.

6. A recipe etching method comprising:
receiving, by an operation of an operator of arranging, on a screen, a plurality of display blocks visually indicating setting of at least one category among a plurality of categories included in a recipe to be executed by a semiconductor manufacturing apparatus, an input of a time during which the setting of the category continues;
receiving, from the operator, an input of a setting value of a setting item included in the setting of the category for each display block arranged on the screen; and
editing the recipe by sequentially arranging steps, each made up of a combination of all setting items set with the setting values and the time during which the setting continues, as a minimum unit, based on the time during which the setting of the category continues and the input of the setting value of the setting item.

7. A semiconductor manufacturing apparatus comprising the information processing apparatus according to claim 1.
